(19) United States
(12) Patent Application Publication
(10) Pub. No.: US 2026/0135551 A1
(43) Pub. Date: May 14, 2026

(54) GATE DRIVER CIRCUIT, MOTOR DRIVING DEVICE USING THE SAME, AND ELECTRONIC APPARATUS

(71) Applicant: ROHM CO., LTD., Kyoto-shi (JP)

(72) Inventor: Hisashi SUGIE, Kyoto-shi (JP)

(21) Appl. No.: 19/374,383

(22) Filed: Oct. 30, 2025

(30) Foreign Application Priority Data
Nov. 8, 2024 (JP) 2024-196304

(51) Int. Cl. H03K 17/06; H03K 17/10

(52) U.S. Cl. CPC H03K 17/063; H03K 17/102; H03K 2217/0036; H03K 2217/0063; H03K 2217/0072

(57) ABSTRACT

A turn-on circuit includes a first current source and a second current source. During a turn-on period, the first current source sources a constant amount of a first current to a gate of a high-side transistor. The second current source includes a plurality of transistors connected in parallel and individually controllable to be turned on and off, wherein a combination of the plurality of transistors that are on changes over time during the turn-on period, and sources a second current, a current amount of which changes depending on the transistors that are on, to a gate of a power transistor. A sum of the first current and the second current is a turn-on current.

### CROSS REFERENCE TO RELATED APPLICATIONS

The present invention claims priority under 35 U.S.C. § 119 to Japanese Application No. 2024-196304, filed on Nov. 8, 2024, the entire contents of which being incorporated herein by reference.

### TECHNICAL FIELD

The present disclosure relates to a gate driver circuit.

### BACKGROUND

Half-bridge circuits, H-bridge circuits, and three-phase bridge circuits (hereinafter collectively referred to as switching circuits) using power transistors are used in motor driver circuits, DC/DC converters, power conversion devices, etc.

FIG. 1 is a circuit diagram of a switching circuit 10. The switching circuit 10 comprises an upper arm 12 and a lower arm 14, which are provided in series between a power supply terminal and a ground terminal. The upper arm 12 includes a high-side transistor MH and a flywheel diode Di connected in parallel. The lower arm 14 includes a low-side transistor ML and a flywheel diode Di connected in parallel. An inductor (coil) L1, which is a load, is connected to an output terminal of the switching circuit 10.

The switching circuit 10 can be in a state φ1 where both the high-side transistor MH and the low-side transistor ML are off (high impedance state), a state φ2 where the high-side transistor MH is on and the low-side transistor ML is off (high output state), or a state φ3 where the high-side transistor MH is off and the low-side transistor ML is on (low output state). For each of the states φ1 to φ3, there exists a current source state where a current I_{OUT} is emitted from the switching circuit 10 (flowing to the right in the figure) and a current sink state where the switching circuit 10 absorbs the current I_{OUT} (flowing to the left in the figure).

### Prior Art Document

### Patent Document

[Patent document 1] Japan Patent Publication No. 2018-82575.
[Patent document 2] International Publication No. WO 2022/259780.

### BRIEF DESCRIPTION OF THE DRAWINGS

FIG. 1 is a circuit diagram of a bridge circuit.

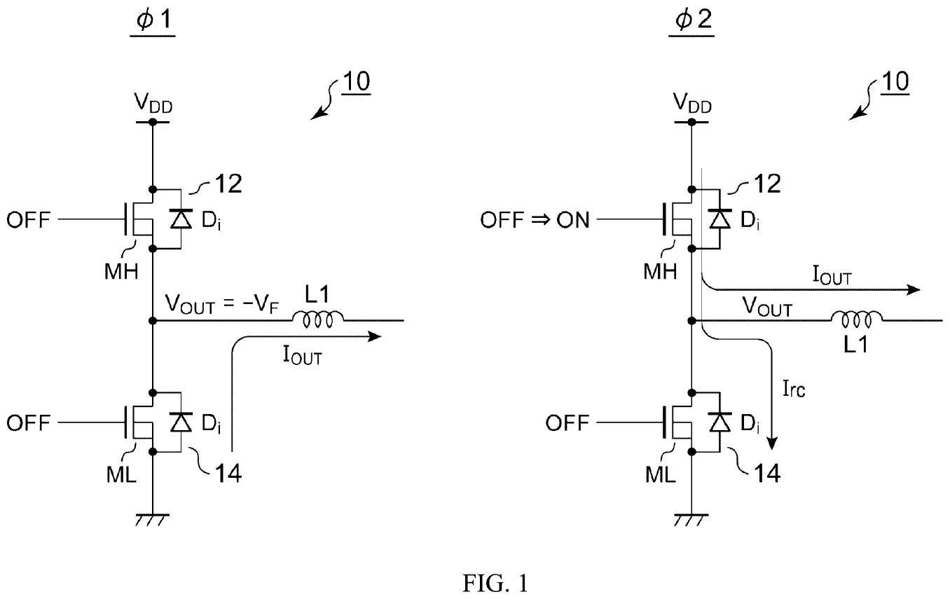

FIG. 2 is a circuit diagram of a switching circuit according to Embodiment 1.

FIG. 3 is an operational waveform diagram of a current source mode of a gate driver circuit in FIG. 2.

FIG. 4 is an operational waveform diagram of a current sink mode of a gate driver circuit in FIG. 2.

FIG. 5 is a circuit diagram of a gate driver circuit according to an embodiment.

FIG. 6 is a waveform diagram illustrating an operation of a turn-on circuit in FIG. 5.

FIG. 7 is a circuit diagram of a turn-on circuit according to an implementation example.

FIG. 8 is a circuit diagram of a turn-on circuit according to an implementation example.

FIG. 9 is a circuit diagram of a turn-on circuit according to an implementation example.

FIG. 10 is a circuit diagram illustrating a switching of a switching circuit.

FIG. 11 is an operational waveform diagram of a switching circuit in FIG. 10.

FIG. 12 is a circuit diagram of a switching circuit according to Embodiment 2.

FIG. 13 is a waveform diagram illustrating an operation of the switching circuit in FIG. 12.

FIG. 14 is a circuit diagram of a gate driver circuit according to Embodiment 2.

FIG. 15 is a circuit diagram of a motor driving device according to an embodiment.

### DETAILED DESCRIPTION OF THE EMBODIMENTS

### Overview of Embodiments

An overview of some exemplary embodiments of the present disclosure is illustrated. This overview serves as a preface to a detailed illustration that follows, is intended to provide a basic understanding of embodiments by simplifying some concepts of one or more embodiments, and is not intended to limit the scope of the invention or disclosure. For convenience, “an embodiment” may be used to refer to one embodiment (implementation example or modification example) or a plurality of embodiments (implementation examples or modification examples) disclosed in this specification.

This overview is not an exhaustive overview of all possible embodiments and is intended to neither identify essential elements of all embodiment nor delineate the scope of some or all aspects. Its sole purpose is to present some concepts of one or more embodiments in a simplified form as a preface to the more detailed illustration that is presented later.

A gate driver circuit according to an embodiment drives an N-type power transistor. The gate driver circuit comprises a turn-on circuit that sources a turn-on current to a gate of the power transistor during a turn-on period, a turn-off circuit that sinks a turn-off current from the gate of the power transistor during a turn-off period, and a control circuit that controls the turn-on circuit and the turn-off circuit. The turn-on circuit includes a first current source that sources a constant amount of a first current to the gate of the power transistor during the turn-on period, and a second current source including a plurality of transistors connected in parallel and individually controllable to be turned on and off, wherein a combination of the plurality of transistors that are on changes over time during the turn-on period, and sourcing a second current, a current amount of which changes depending on the transistors that are on, to the gate of the power transistor. A sum of the first current and the second current is the turn-on current.

A current driving capability (simply referred to as driving capability or capability) of the second current source is the sum of driving capabilities of the transistors that are in the on state among the plurality of transistors, and the driving capability of each transistor is defined by its size, i.e., the W/L (ratio of gate width/gate length). During the turn-on period, after the power transistor is turned on, and during the period when a reverse recovery current may flow through a flywheel diode of an opposite arm, a current driving capability of the second current source is reduced to gradually turn on the power transistor while maintaining a large on-resistance. As a result, a shoot-through current and ringing caused by the reverse recovery current of the flywheel diode in the opposite arm can be suppressed.

In this configuration, the turn-on current is the sum of the first current and the second current, where the first current has a constant amount, and only a current amount of the second current changes. Therefore, the turn-on current can be prevented from becoming zero at the timing of switching.

In one embodiment, the first current source may include a constant current source that generates a reference current and a current mirror circuit that copies the reference current and generates the first current.

In one embodiment, the first current source may include a plurality of transistors connected in parallel and individually controllable to be turned on and off, and a current amount of the first current may depend on a combination of transistors that are on.

In one embodiment, it may be that during a minimum current interval of a part of the turn-on period, the plurality of transistors of the second current source are all turned off and the second current is zero. As a result, the turn-on current can be prevented from becoming zero at the timing of transition to the minimum current interval, and surging (a glitch) of the turn-on current can be prevented at the timing of transition from the minimum current interval to the next interval.

In one embodiment, it may be that during a first interval before the minimum current interval of the turn-on period, at least one of the plurality of transistors is turned on, and the second current source generates the second current, the current amount of which is non-zero. During the first interval, where the possibility of reverse recovery current is low, a turn-on current greater than that in the minimum current interval is supplied, so a rate at which a gate voltage of the power transistor rises can be increased, and a turn-on period for the power transistor can be shortened. As a result, the power consumption of the power transistor can be reduced.

In one embodiment, it may be that during a third interval after the minimum current interval of the turn-on period, at least one of the plurality of transistors is turned on, and the second current source generates the second current, the current amount of which is non-zero. During the third interval, where the possibility of reverse recovery current is low, by increasing a current amount of a turn-on current beyond that during the minimum current interval, a turn-on time of the power transistor can be shortened, and the power consumption can be reduced.

In one embodiment, the second current during the third interval may be greater than the second current during the first interval. After the influence of reverse recovery characteristics of the flywheel diode of the opposite arm becomes small, by increasing the current amount of the turn-on current, the on-resistance of the power transistor can be reduced in a short time, and the efficiency of the bridge circuit can be improved.

In one embodiment, sizes of the plurality of transistors constituting the second current source may be binary weighted.

In one embodiment, the turn-off circuit may include a third current source that sinks a constant amount of a third current from the gate of the power transistor during the turn-off period, and a fourth current source including a plurality of transistors connected in parallel and individually controllable to be turned on and off, wherein a combination of the plurality of transistors that are on changes over time during the turn-off period, and sinking a fourth current, a current amount of which changes depending on the transistors that are on, from the gate of the power transistor, wherein a sum of the third current and the fourth current may be the turn-off current.

With this configuration, during an interval where a drain current flowing through the power transistor is substantially constant, by increasing the turn-off current, the turn-off time can be shortened, and the power consumption can be reduced. Additionally, during the period where the drain current changes, by reducing the turn-off current, a rate of change of the high-side current can be reduced, and EMI can be suppressed. Additionally, the negative voltage generated at the output can be suppressed. The turn-off current is the sum of the third current and the fourth current, where the third current has a constant amount, and only a current amount of the fourth current changes. Therefore, the turn-off current can be prevented from becoming zero at the timing of switching.

In one embodiment, the gate driver circuit may be monolithically integrated on a single semiconductor substrate. “Monolithically integrated” includes a case where all components of the circuit are formed on a semiconductor substrate, or a case where main components of the circuit are monolithically integrated, and some resistors, capacitors, etc., for adjusting circuit constants may be provided outside the semiconductor substrate. By integrating the circuit onto a single chip, the circuit area can be reduced, and characteristics of circuit elements can be kept uniform.

A motor driving circuit according to one embodiment comprises a bridge circuit including a high-side transistor and a low-side transistor, a high-side driver which is any of the aforementioned gate driver circuits that drives the high-side transistor as the power transistor, and a low-side driver which is any of the aforementioned gate driver circuits that drives the low-side transistor as the power transistor.

An electronic apparatus according to one embodiment comprises a motor and the aforementioned motor driving device that drives the motor.

### Embodiments

Hereinafter, preferable embodiments are illustrated with reference to figures. Identical or equivalent elements, components, processes shown in each figure are denoted by same reference numerals, and redundant illustrations are omitted as appropriate. Additionally, the embodiments are exemplary and do not limit the invention, and all features or combinations thereof illustrated in the embodiments are not necessarily essential to the invention.

In this specification, the phrase “a state in which component A is connected to component B” includes not only cases in which the component A and the component B are physically directly connected, but also cases in which the component A and the component B are indirectly connected to each other via other components that do not substantially affect their electrical connection state or do not impair functions or effects achieved by their combination.

Similarly, the phrase “a state in which component C is disposed between component A and component B” includes not only cases in which the component A and the component C, or the component B and the component C, are directly connected, but also cases in which they are indirectly connected via other components that do not substantially affect their electrical connection state or do not impair functions or effects achieved by their combination.

### Embodiment 1

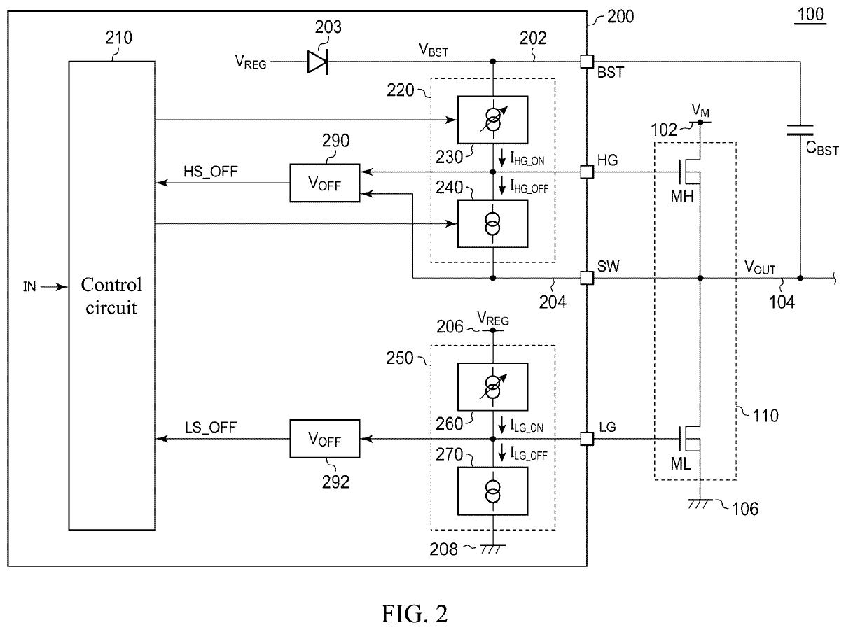

FIG. 2 is a circuit diagram of a switching circuit 100 according to Embodiment 1. The switching circuit 100 comprises a bridge circuit 110 and a gate driver circuit 200. Herein, only a configuration of one phase of the switching circuit 100 is shown, but the switching circuit 100 may be three-phase, or it may also be a H-bridge circuit.

The bridge circuit 110 comprises a high-side transistor MH provided between a power supply line (input line) 102 and an output terminal (output line) 104, and a low-side transistor ML provided between the output line 104 and a ground line 106. An input voltage V_{M} is supplied to the input line 102. In this embodiment, the high-side transistor MH and the low-side transistor ML are N-channel MOSFETs, and their respective body diodes also serve as flywheel diodes.

The gate driver circuit 200 drives the high-side transistor MH and the low-side transistor ML of the bridge circuit 110.

A bootstrap capacitor C_{BST} is connected between a bootstrap pin BST and the output line 104. A high-side gate pin HG is connected to a gate of the high-side transistor MH. A switching pin SW is connected to a source of the high-side transistor MH and a drain of the low-side transistor ML. A low-side gate pin LG is connected to a gate of the low-side transistor ML.

A bootstrap line 202 is connected to the bootstrap pin BST. A regulated voltage V_{REG} is applied to the bootstrap line 202 via a rectifying element 203. The rectifying element 203 and the bootstrap capacitor C_{BST} form a bootstrap circuit, maintaining a voltage V_{BST} on the bootstrap line 202 at V_{OUT}+V_{REG}−Vf. Vf is a forward voltage of the rectifying element 203.

The gate driver circuit 200 comprises a control circuit 210, a high-side driver 220, a low-side driver 250, a high-side off sensor 290, and a low-side off sensor 292, and is a functional IC integrated on a single semiconductor substrate. The control circuit 210 controls the high-side driver 220 and the low-side driver 250 according to an input signal IN.

The high-side driver 220 comprises a turn-on circuit 230 and a turn-off circuit 240. The turn-on circuit 230 is connected between the bootstrap line 202 and the high-side gate pin HG. The turn-on circuit 230 becomes active when the high-side transistor MH is turned on and sources a gate current (turn-on current) I_{HG_ON} to the gate of the high-side transistor MH. A gate capacitance of the high-side transistor MH is charged by the turn-on current I_{HG_ON}, and a gate-source voltage of the high-side transistor MH increases.

The turn-off circuit 240 is connected between the high-side gate pin HG and the switching line 204. The turn-off circuit 240 becomes active when the high-side transistor MH is turned off and sinks a gate current (turn-off current) I_{HG_OFF} from the gate of the high-side transistor MH. The gate capacitance of the high-side transistor MH is discharged by the turn-off current I_{HG_OFF}, and the gate-source voltage of the high-side transistor MH decreases.

The low-side driver 250 comprises a turn-on circuit 260 and a turn-off circuit 270. The turn-on circuit 260 is connected between a power supply line 206 and the low-side gate pin LG. The turn-on circuit 260 becomes active when the low-side transistor ML is turned on and sources a gate current (turn-on current) I_{LG_ON} to the gate of the low-side transistor ML. A gate capacitance of the low-side transistor ML is charged by the turn-on current I_{LG_ON}, and a gate-source voltage of the low-side transistor ML increases.

The turn-off circuit 270 is connected between the low-side gate pin LG and the ground line 208. The turn-off circuit 270 becomes active when the low-side transistor ML is turned off and sinks a gate current (turn-off current) I_{LG_OFF} from the gate of the low-side transistor ML. A gate capacitance of the low-side transistor ML is discharged by a turn-off current I_{LG_OFF}, and a gate-source voltage of the low-side transistor ML decreases.

The high-side off sensor 290 asserts (for example, high) a high-side off detection signal HS_OFF when it detects that the high-side transistor MH is turned off. For example, the high-side off sensor 290 compares a gate-source voltage V_{HGS} of the high-side transistor MH with a predetermined threshold voltage V_{OFF}, and when V_{HGS}<V_{OFF}, it asserts the high-side off detection signal HS_OFF.

The low-side off sensor 292 asserts (for example, high) a low-side off detection signal LS_OFF when it detects that the low-side transistor ML is turned off. For example, the low-side off sensor 292 compares a gate-source voltage V_{LGS} of the low-side transistor ML with a predetermined threshold voltage V_{OFF}, and when V_{LGS}<V_{OFF}, it asserts the low-side off detection signal LS_OFF.

When the input signal IN is at a first level (for example, high), the control circuit 210 controls the high-side driver 220 and the low-side driver 250 such that the high-side transistor MH is on and the low-side transistor ML is off. Additionally, when the input signal IN is at a second level (for example, low), the control circuit 210 controls the high-side driver 220 and the low-side driver 250 such that the high-side transistor MH is off and the low-side transistor ML is on.

When the input signal IN changes from the first level to the second level, the control circuit 210 turns off the high-side transistor MH and subsequently turns on the low-side transistor ML. Specifically, it activates the turn-off circuit 240 of the high-side driver 220. As a result, the turn-off current I_{HG_OFF} is sunk from the gate of the high-side transistor MH, and the high-side transistor MH is turned off. When the high-side transistor MH is turned off, the high-side off detection signal HS_OFF is asserted.

In response to the assertion of the high-side off detection signal HS_OFF, the control circuit 210 activates the turn-on circuit 260 of the low-side driver 250. As a result, the turn-on current I_{LG_ON} is sourced to the gate of the low-side transistor ML, and the low-side transistor ML is turned on.

When the input signal IN changes from the second level to the first level, the control circuit 210 turns off the low-side transistor ML and subsequently turns on the high-side transistor MH. Specifically, it activates the turn-off circuit 270 of the low-side driver 250. As a result, the turn-off current I_{LG_OFF} is sunk from the gate of the low-side transistor ML, and the low-side transistor ML is turned off. When the low-side transistor ML is turned off, the low-side off detection signal LS_OFF is asserted.

In response to the assertion of the low-side off detection signal LS_OFF, the control circuit 210 activates the turn-on circuit 230 of the high-side driver 220. As a result, the turn-on current I_{HG_ON} is sourced to the gate of the high-side transistor MH, and the high-side transistor MH is turned on.

In this embodiment, the turn-on circuit 230 of the high-side driver 220 is configured to be able to switch the turn-on current I_{HG_ON} in multiple stages. When the bridge circuit 110 operates in a current source mode, the control circuit 210 controls not only the on and off states of the turn-on circuit 230 but also a current amount of the turn-on current I_{HG_ON} generated by the turn-on circuit 230.

Specifically, in an operation mode (source mode) where the output current I_{OUT} of the bridge circuit 110 flows toward a load (not shown), the control circuit 210 controls the turn-on circuit 230 of the high-side driver 220 as follows.

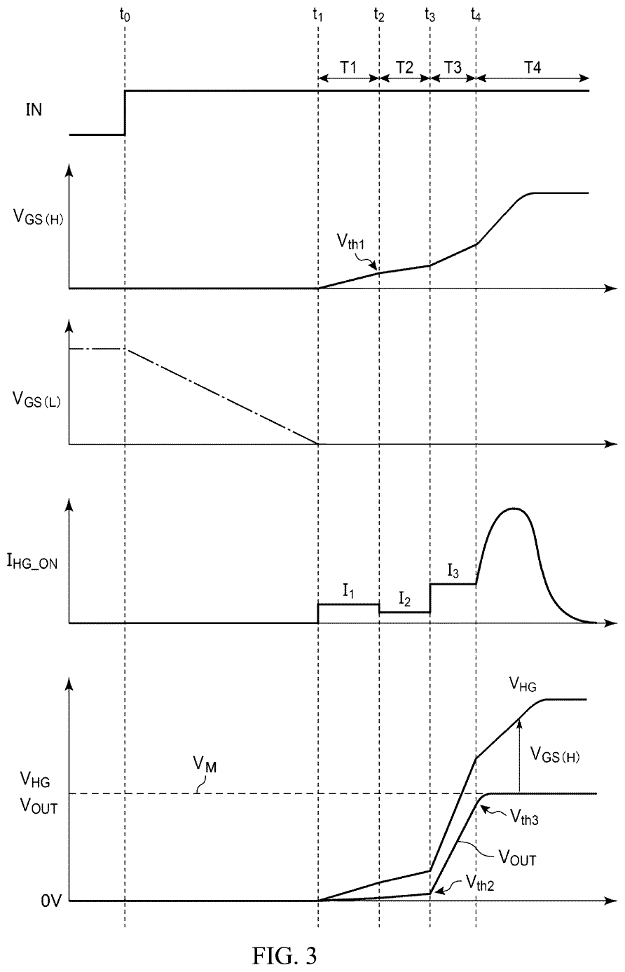

FIG. 3 is an operational waveform diagram of a current source mode of a gate driver circuit 200 in FIG. 2. The input signal IN is a logic signal indicating a state of the bridge circuit 110. V_{GS(L)} is a gate voltage (gate-source voltage) of the low-side transistor ML. V_{HG} is a gate voltage of the high-side transistor MH, and V_{OUT} indicates a source voltage, i.e., an output voltage, of the high-side transistor MH. V_{GS(H)} is a gate-source voltage of the high-side transistor MH, which is a potential difference between V_{HG} and V_{OUT}.

Before time t₀, the input signal IN is at a low level, the high-side transistor MH is off, the low-side transistor ML is on, and the output voltage V_{OUT} is at a low voltage (0 V).

FIG. 3 shows an operation in the current source mode, where before time t₀, a negative current I_{ML} flows through the low-side transistor ML.

At time t₀, the input signal IN transitions to a high level. As a result, the low-side driver 250 reduces the gate voltage V_{LG} of the low-side transistor ML, turning off the low-side transistor ML.

At time t₁, when the gate voltage V_{LG} of the low-side transistor ML falls below a predetermined threshold voltage, the low-side off detection signal LS_OFF is asserted. In response to the assertion of the low-side off detection signal LS_OFF, the control circuit 210 sets the turn-on circuit 230 of the high-side driver 220 to an enabled state.

During a first period T1, the turn-on circuit 230 generates a turn-on current I_{HG_ON} having a first current amount I₁.

Then, when the gate-source voltage V_{GS(H)} of the high-side transistor MH exceeds a first threshold voltage Vₜₕ₁ at time t₂, a transition occurs to a second period T2 (minimum current interval). During the second period T2, the turn-on current I_{HG_ON} becomes a minimum current amount I₂.

Since the current amount I₂ during the minimum current interval is less than the current amount I₁ of the first period T1, a rate of increase of the gate-source voltage V_{GS(H)} becomes slower than that in the first period T1.

Then, when the output voltage V_{OUT} exceeds a second threshold voltage Vₜₕ₂ at time t₃, a transition occurs to a third period T3. During the third period T3, the turn-on current I_{HG_ON} becomes a third current amount I₃, which is greater than the minimum current amount I₂. The third current amount I₃ may be greater than the first current amount I₁. As a result, a rate of increase of the gate-source voltage V_{GS(H)} during the third period T3 becomes faster.

Then, when the output voltage V_{OUT} exceeds the third threshold voltage Vₜₕ₃ determined to be near the input voltage V_{M} at time t₄, a transition occurs to a fourth period T4. During the fourth period T4, the turn-on circuit 230 enters a strong-on state, the gate voltage V_{HG} of the high-side transistor MH is kept at a high-level voltage (bootstrap voltage V_{BST}), and the high-side transistor MH is kept at a strong-on state.

The above is the operation of the switching circuit 100.

With this switching circuit 100, a period immediately before the high-side transistor MH is turned on is defined as the first period T1, during which the turn-on current I_{HG_ON} having the first current amount I₁ is supplied to the gate of the high-side transistor MH, and the gate voltage V_{HG} is increased. Then, during the second period (minimum current interval) T2, which is a period after the high-side transistor MH is turned on, during which a reverse recovery current may flow through the flywheel diode of the lower arm, by reducing the turn-on current I_{HG_ON} supplied to the gate of the high-side transistor MH to the second current amount I₂, the high-side transistor MH is turned on gradually while maintaining a large on-resistance. As a result, a shoot-through current and ringing caused by the reverse recovery current of the flywheel diode on the opposite side (i.e., the low side) of the high-side transistor MH, which is the drive target of the gate driver circuit 200, can be suppressed.

Subsequently, during the third period T3 where the possibility of the reverse recovery current flowing is low, the turn-on current I_{HG_ON} supplied to the gate of the high-side transistor MH is increased to the third current amount I₃ that is greater than that during the second period T2, so that a turn-on time of the high-side transistor MH can be shortened and the power consumption can be reduced.

Moreover, during the third period T3, the turn-on current I_{HG_ON} supplied to the gate of the high-side transistor MH is greater than the first current amount I₁ of the first period T1. As a result, the on-resistance of the high-side transistor MH can be reduced in a short time, and the efficiency of the bridge circuit can be further improved.

Similarly, the turn-on circuit 260 of the low-side driver 250 is also configured to be able to switch the turn-on current I_{LG_ON} in multiple stages. When the bridge circuit 110 operates in a current sink mode, the control circuit 210 controls the current amount of the turn-on current I_{LG_ON} generated by the turn-on circuit 260, in addition to the on and off states of the turn-on circuit 260.

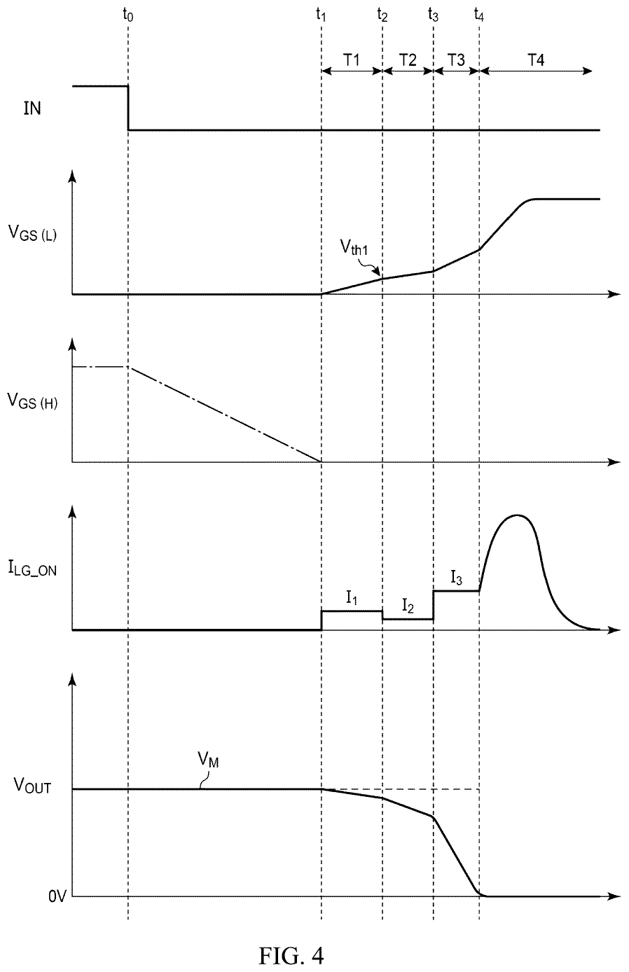

FIG. 4 is an operation waveform diagram of a current sink mode of the gate driver circuit 200 in FIG. 2.

Before time t₀, the input signal IN is at a high level, the high-side transistor MH is on, the low-side transistor ML is off, and the output voltage V_{OUT} is equal to the input voltage V_{M}.

At time t₀, the input signal IN transitions to a low level. As a result, the turn-off circuit 240 reduces the gate voltage V_{HG} of the high-side transistor MH, turning off the high-side transistor MH.

At time t₁, when the gate-source voltage V_{GS(H)} of the high-side transistor MH becomes lower than a predetermined threshold voltage, the high-side off detection signal HS_OFF is asserted. In response to the assertion of the high-side off detection signal HS_OFF, the control circuit 210 sets the turn-on circuit 260 of the low-side driver 250 to be an enabled state.

During the first period T1, the turn-on circuit 260 generates the turn-on current I_{LG_ON} having the first current amount I₁.

Then, when a gate-source voltage V_{GS(L)} of the low-side transistor ML exceeds the first threshold voltage Vₜₕ₁ at time t₂, a transition occurs to the second period T2 (minimum current interval). During the second period T2, the turn-on current I_{LG_ON} becomes the minimum current amount I₂.

Since the current amount I₂ during the minimum current interval T2 is less than the current amount I₁ during the first period T1, a rate of increase of the gate-source voltage V_{GS(L)} becomes slower than that during the first period T1.

Then, when the output voltage V_{OUT} decreases to a predetermined threshold voltage at time t₃, a transition occurs to the third period T3. During the third period T3, the turn-on current I_{HG_ON} becomes a third current amount I₃ that is greater than the minimum current amount I₂. The third current amount I₃ may be greater than the first current amount I₁. As a result, a rate of increase of the gate-source voltage V_{GS(L)} during the third period T3 becomes faster.

Then, when the output voltage V_{OUT} decreases to a threshold voltage determined to be near 0 V at time t₄, a transition occurs to the fourth period T4. During the fourth period T4, the turn-on circuit 260 enters a strong-on state, the gate voltage V_{LG} of the low-side transistor ML is kept at a high-level voltage, and the low-side transistor ML is kept at a strong-on state.

With this control, the shoot-through current and ringing caused by the reverse recovery current of the high-side flywheel diode can be suppressed.

Next, a specific configuration of the gate driver circuit 200 is illustrated.

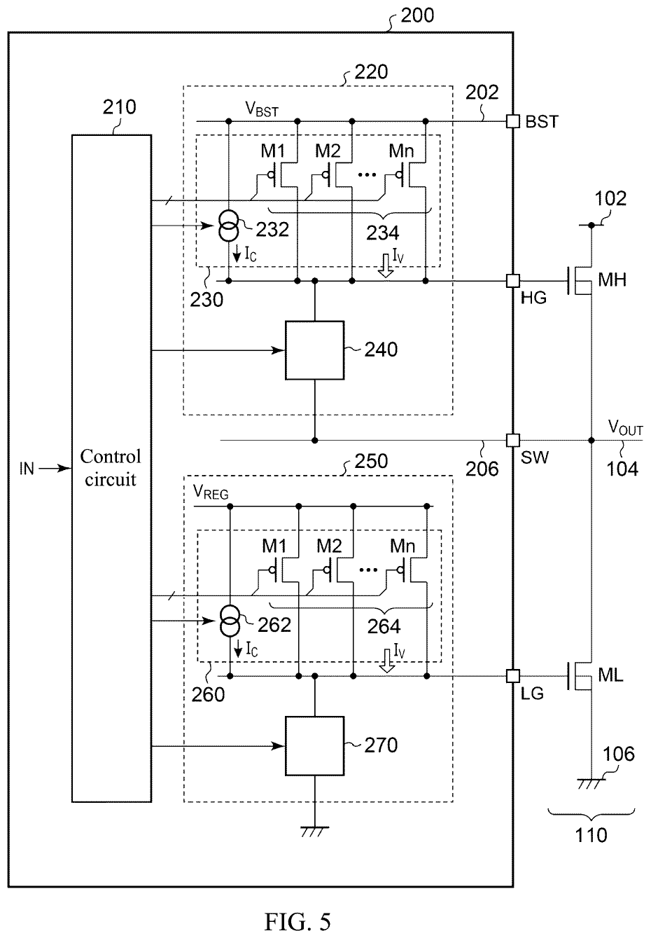

FIG. 5 is a circuit diagram of the gate driver circuit 200 according to an embodiment.

The turn-on circuit 230 includes a first current source 232 and a second current source 234. The first current source 232 sources a constant amount of a first current I_{C} to the gate of the power transistor to be driven, i.e., the high-side transistor MH, during the turn-on periods T1 to T3.

The second current source 234 includes a plurality of transistors M1, M2, . . . Mn (n≥2) that are connected in parallel and individually controllable to be turned on or off. During the turn-on periods T1 to T3, a combination of the plurality of transistors of the second current source 234 that are on changes over time. The plurality of transistors M1 to Mn are PMOS transistors, and their sizes (W/L) are designed to operate in a non-saturation region.

The second current source 234 sources a second current I_{V}, whose current amount changes according to a combination of the transistors that are on, to the gate of the high-side transistor MH. A sum of the first current I_{C} and the second current I_{V} is the turn-on current I_{HG_ON}.

The turn-on circuit 260 is configured similarly to the turn-on circuit 230 and includes a first current source 262 and a second current source 264. The first current source 262 sources a constant amount of the first current I_{C} to the gate of the power transistor to be driven, i.e., the low-side transistor ML, during the turn-on periods T1 to T3.

The second current source 264 is configured similarly to the second current source 234. Specifically, the second current source 264 includes a plurality of transistors M1, M2, . . . Mn (n≥2) that are connected in parallel and individually controllable to be turned on and off. During the turn-on periods T1 to T3, a combination of the plurality of transistors of the second current source 264 that are on changes over time.

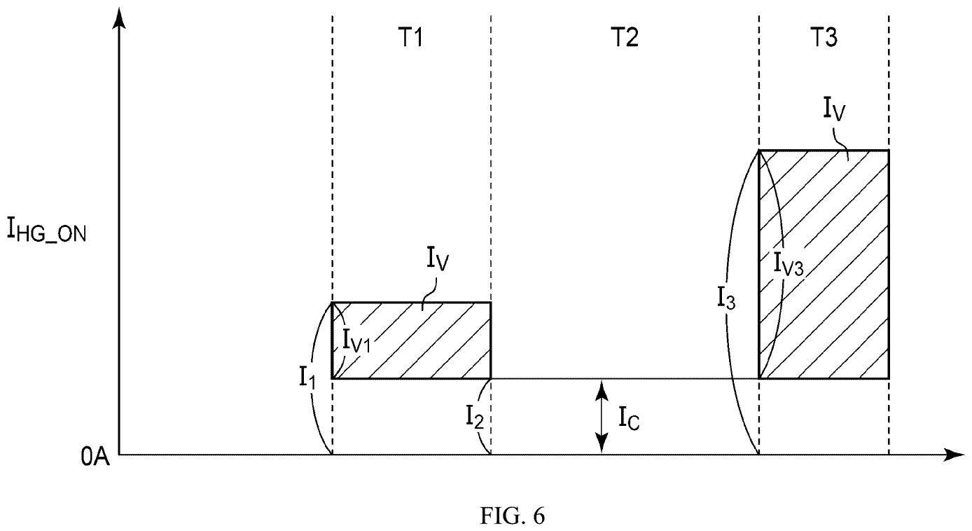

FIG. 6 is a waveform diagram illustrating an operation of the turn-on circuit 230 in FIG. 5. During the first period T1 to the third period T3, the first current source 232 is on, generating a first current I_{C} which is constant. In the first period T1, some of the transistors M1 to Mn of the second current source 234 are on, generating a second current I_{V1}. In the second period T2, all of the transistors M1 to Mn of the second current source 234 are off, and the second current I_{V} is 0. In the third period T3, some of the transistors M1 to Mn of the second current source 234 are on, generating a second current I_{V3}.

With the turn-on circuit 230 in FIG. 5, the current can be prevented from becoming zero or from surging significantly during the switching between the first period T1, the second period T2, and the third period T3.

The same applies to the turn-on circuit 260.

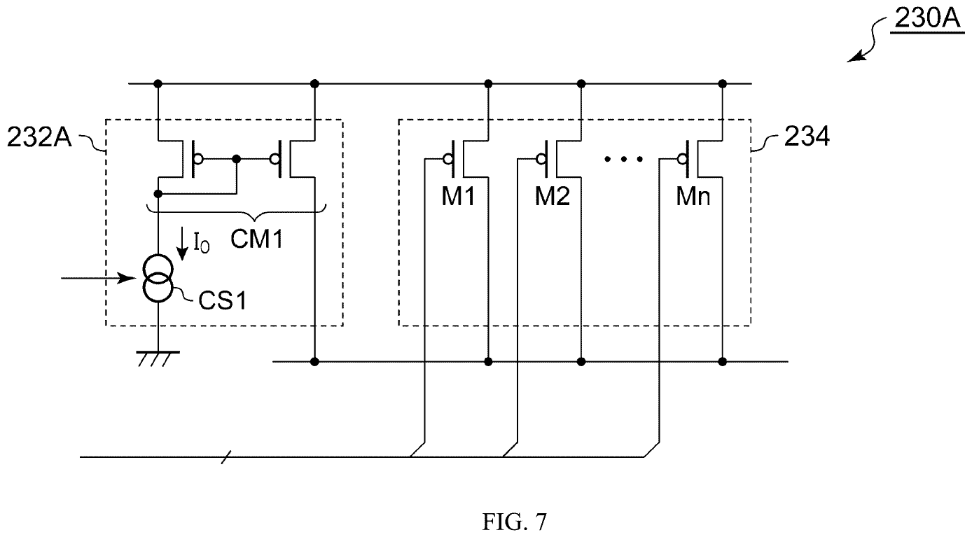

FIG. 7 is a circuit diagram of a turn-on circuit 230A according to an implementation example. A first current source 232A includes a constant current source CS1 and a current mirror circuit CM1. The constant current source CS1 generates a reference current I₀. The current mirror circuit CM1 copies and reflects the reference current I₀ to generate the first current I_{C}.

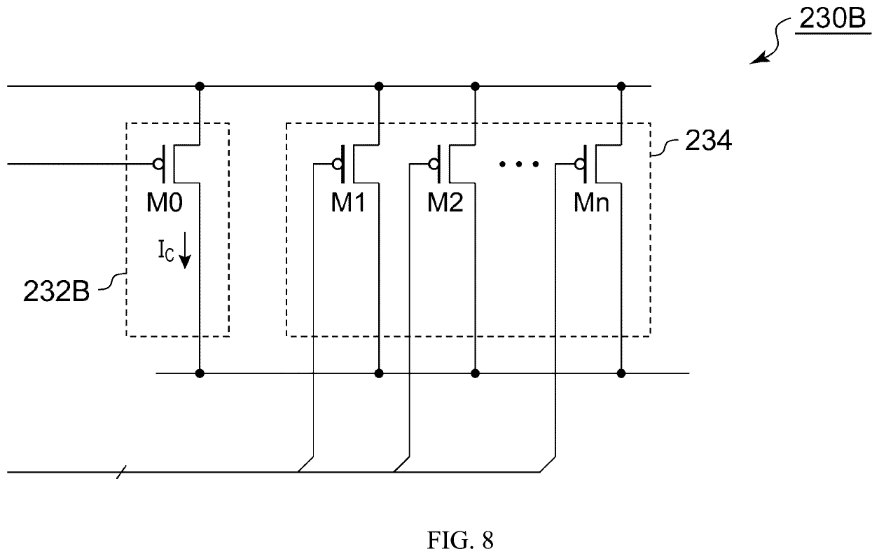

FIG. 8 is a circuit diagram of a turn-on circuit 230B according to an implementation example. A first current source 232B is a transistor M0, which includes one or a plurality of PMOS transistors connected in parallel, and a current flowing through the transistor M0 is the first current I_{C}.

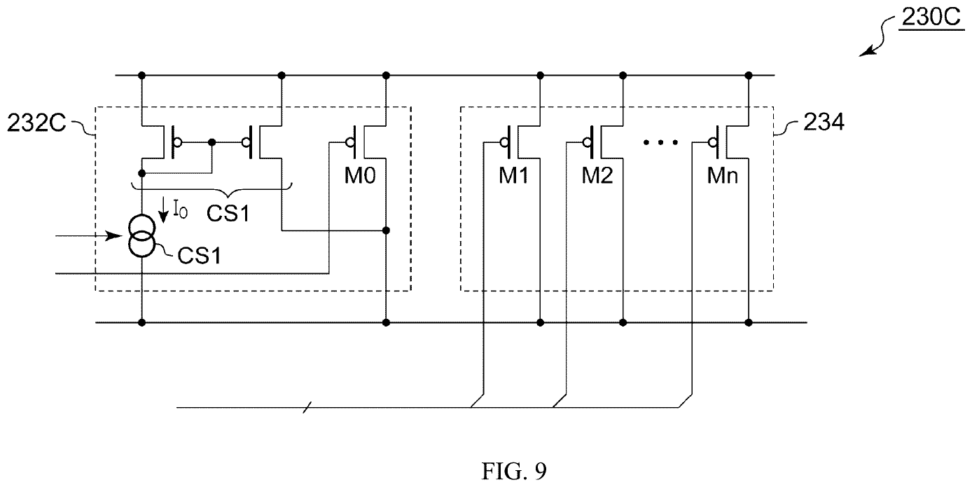

FIG. 9 is a circuit diagram of a turn-on circuit 230C according to an implementation example. A first current source 232C is a combination of the first current source 232A in FIG. 7 and the first current source 232B in FIG. 8, and includes the constant current source CS1, the current mirror circuit CM1, and the transistor M0.

### Embodiment 2

In Embodiment 1, a configuration to solve issues when the high-side transistor MH and the low-side transistor ML (collectively referred to as power transistors) are turned on are illustrated. In Embodiment 2, a configuration to solve issues when the high-side transistor MH and the low-side transistor ML (collectively referred to as power transistors) are turned off are illustrated.

First, the issues that arise when the power transistors are turned off in a switching circuit are illustrated.

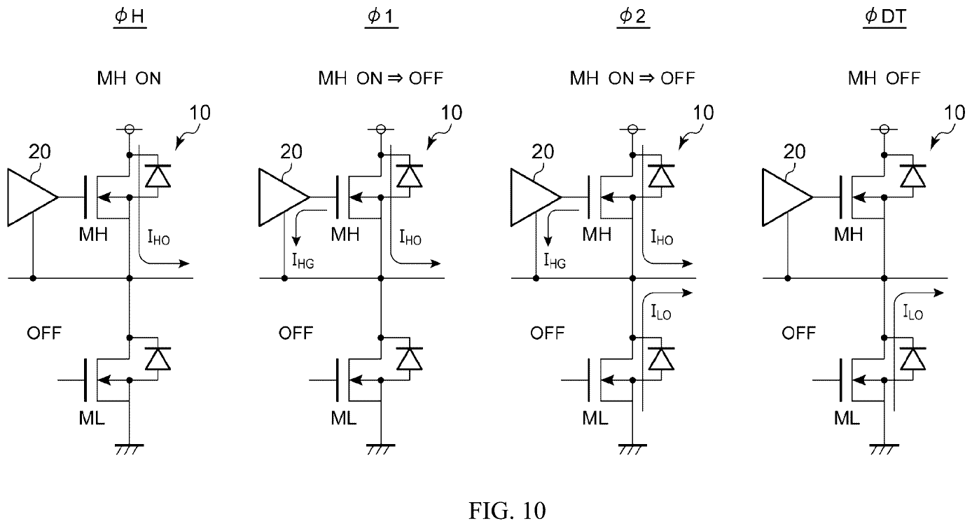

FIG. 10 is a circuit diagram illustrating a switching of a switching circuit 10. Herein, a turn-off operation of a high-side transistor are illustrated. The switching circuit 10 includes a high-side transistor MH and a low-side transistor ML provided in series between a power supply terminal and a ground terminal.

The switching circuit 10 in FIG. 10 operates in a current source mode, supplying a current I_{OUT} from the switching circuit 10 to a load (not shown).

A state φ_{H} indicates a high output state where the high-side transistor MH is on and the low-side transistor ML is off. The high-side current I_{HO} flowing from a power supply line via the high-side transistor MH is supplied to the load as the output current I_{OUT}.

States φ1 and φ2 indicate a turn-off period of the high-side transistor MH. A high-side driver 20 draws a gate current I_{HG} having a constant current from the gate of the high-side transistor MH, gradually reducing a gate-source voltage of the high-side transistor MH over time. In the state φ1, the load current is mainly a high-side current I_{HO} flowing through the high-side transistor MH. In the state φ2, the load current is a sum of the high-side current I_{HO} flowing through the high-side transistor MH and a current I_{LO} flowing through a body diode of the low-side transistor ML.

A state φ_{DT} indicates a dead time state where both the high-side transistor MH and the low-side transistor ML are off. At this time, the load is supplied from the body diode of the low-side transistor ML.

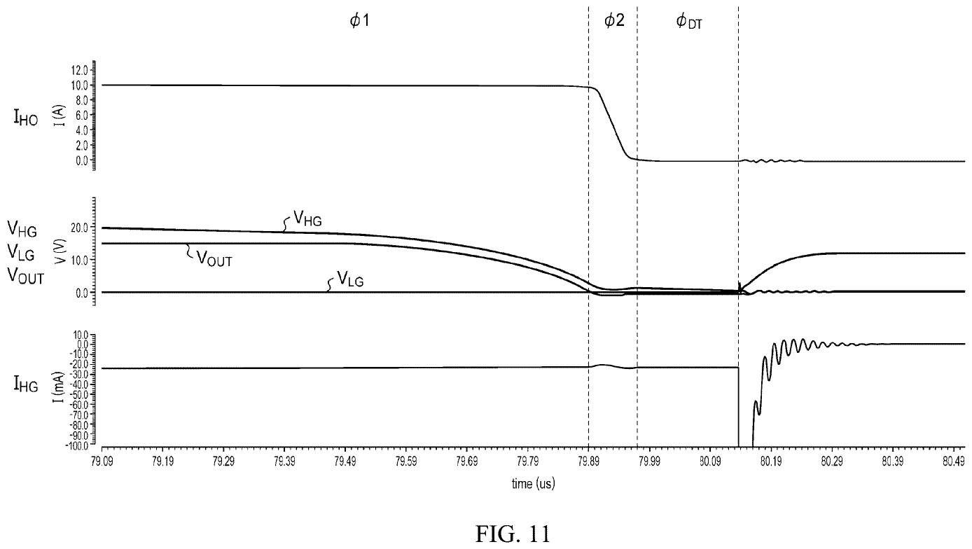

FIG. 11 is an operational waveform diagram of the switching circuit 10 in FIG. 10. In the states φ1 and φ2, the high-side driver 20 is assumed to sink a constant amount of the gate current I_{HG} from the gate of the high-side transistor MH. The gate current I_{HG} is assumed to be positive when flowing into the gate of the high-side transistor MH and negative when drawn out of the gate.

In a control where the gate current I_{HG} is set to a constant amount, if the gate current I_{HG} is small, the power consumption of the high-side transistor MH increases, and an amount of heat generated increases.

Conversely, if the gate current I_{HG} is increased, the power consumption of the high-side transistor MH decreases, but a slope of the high-side current I_{HO} flowing through the high-side transistor MH in the state φ2 becomes steep, and the EMI becomes large. Additionally, if the slope of the high-side current I_{HO} in the state φ2 is steep, the output voltage V_{OUT} becomes a large negative voltage until the body diode of the low-side transistor ML conducts.

As such, in control where the gate current I_{HG} is set to a constant amount, there is a trade-off relationship between the power consumption of the high-side transistor MH and EMI, as well as the negative voltage of output.

In the following, a gate driver circuit capable of suppressing EMI and negative voltage while suppressing power consumption is illustrated.

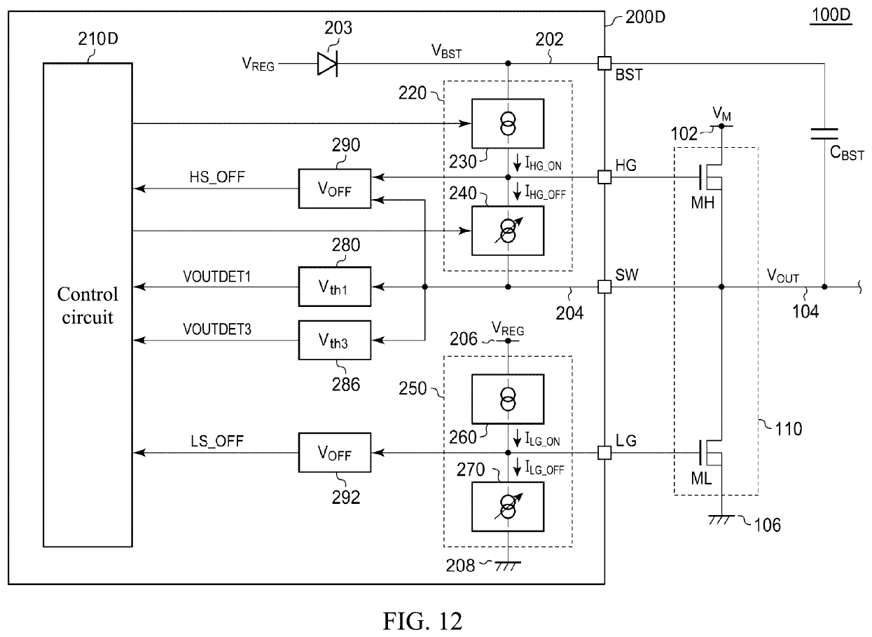

FIG. 12 is a circuit diagram of a switching circuit 100D according to Embodiment 2. A basic configuration of a gate driver circuit 200D is similar to that of the gate driver circuit 200 in FIG. 2. In Embodiment 2, the turn-off circuit 240 of the high-side driver 220 is configured to be able to switch the turn-off current I_{HG_OFF} in multiple stages. Additionally, the turn-off circuit 270 of the low-side driver 250 is configured to be able to switch the turn-off current I_{LG_OFF} in multiple stages.

The gate driver circuit 200D comprises a first output sensor 280 and a second output sensor 286.

The first output sensor 280 is connected to the switching line 204 and monitors the output voltage V_{OUT}. When the output voltage V_{OUT} falls below the first threshold voltage Vₜₕ₁, the first output sensor 280 asserts (for example, high) a first output detection signal VOUTDET1.

The second output sensor 286 is connected to the switching line 204 and monitors the output voltage V_{OUT}. When the output voltage V_{OUT} falls below the third threshold voltage Vₜₕ₃, the second output sensor 286 asserts (for example, high) a third output detection signal VOUTDET3.

When the bridge circuit 110 operates in a current source mode, the control circuit 210D controls the on/off of the turn-off circuit 240 and also a current amount of the turn-off current I_{HG_OFF} generated by the turn-off circuit 240 as follows.

In response to an instruction to turn off the high-side transistor MH, the control circuit 210D sets the gate current I_{HG_OFF} of the turn-off circuit 240 to the first current amount I₁. Then, in response to the assertion of the first output detection signal VOUTDET1, the gate current I_{HG_OFF} is set to the second current amount I₂ that is less than the first current amount I₁.

In response to the assertion of the high-side off signal HS_OFF, the control circuit 210 activates the low-side driver 250 and starts the turn-on operation of the low-side transistor ML.

Additionally, in response to the assertion of the high-side off signal HS_OFF, the control circuit 210D controls the turn-off circuit 240 to keep the gate-source voltage V_{HGS} of the high-side transistor MH at 0 V. For example, the turn-off circuit 240 may include an off-fixed switch connected between a gate and a source of the high-side transistor MH, and by turning on this off-fixed switch, the gate-source voltage V_{HGS} of the high-side transistor MH can be kept at 0 V.

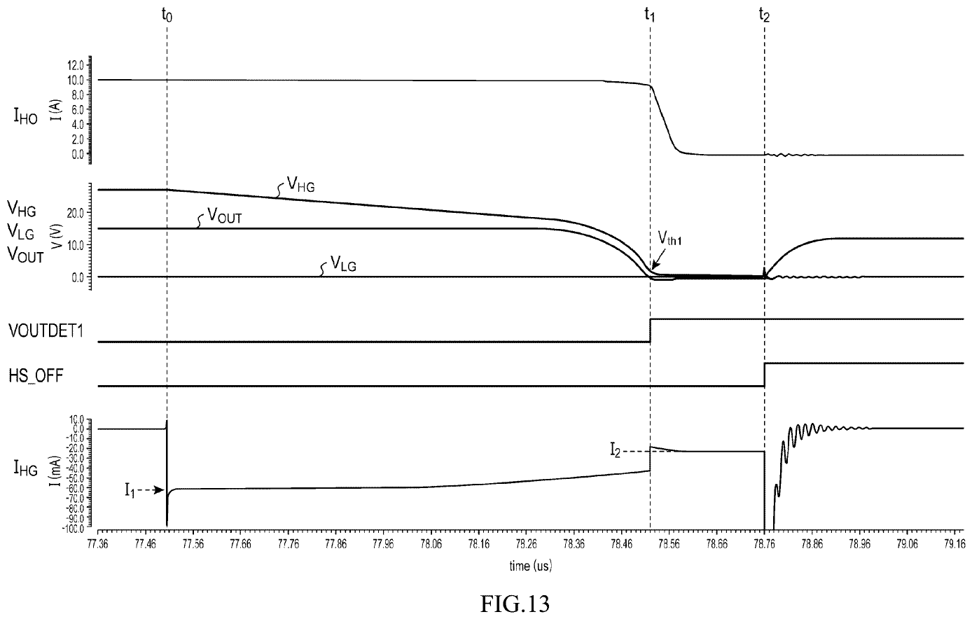

FIG. 13 is a waveform diagram illustrating an operation of the switching circuit 100D in FIG. 12. The switching circuit 100D operates in a current source mode.

At time t₀, when a command to turn off the high-side transistor MH is issued, the control circuit 210 sets the gate current I_{HG} to the first current amount I₁ and activates the turn-off circuit 240 of the high-side driver 220.

At time t₁, when the output voltage V_{OUT} falls below the first threshold voltage Vₜₕ₁, the first output detection signal VOUTDET1 is asserted. In response to the assertion of the first output detection signal VOUTDET1, the control circuit 210 sets the gate current I_{HG} to the second current amount I₂.

At time t₂, when the gate-source voltage V_{HGS} of the high-side transistor MH decreases to a threshold voltage V_{OFF}, the high-side off signal HS_OFF is asserted.

When the high-side off signal HS_OFF is asserted, the gate-source voltage V_{HGS} of the high-side transistor MH is kept at 0 V.

Additionally, in response to the assertion of the high-side off signal HS_OFF, the low-side driver 250 becomes active and starts a turn-on operation of the low-side transistor ML.

The above is the operation of the switching circuit 100D.

In the timing chart of FIG. 13, the period t₀ to t₁ corresponds to the state φ1 in FIG. 10, and the period t₁ to t₂ corresponds to the state φ2 in FIG. 10. With the gate driver circuit 200D according to Embodiment 2, a transition from the state φ1 to φ2 is detected by the first output sensor 280, and in the state φ1, by increasing a current amount of the gate current I_{HG_OFF}, the turn-off time can be shortened, and the power consumption of the high-side transistor MH can be reduced. Additionally, in the state φ2, by reducing the current amount of the gate current I_{HG_OFF}, the slope of the high-side current I_{HO} can be reduced, and EMI can be suppressed. Additionally, the generation of negative voltage in the output voltage V_{OUT} can be suppressed.

The gate current I_{HG_OFF} may be switched in three or more stages.

The control circuit 210D controls the turn-off circuit 270 as follows in an operation mode (sink mode) where the output current I_{OUT} of the bridge circuit 110 flows from the load (not shown).

In response to the instruction to turn off the low-side transistor ML, the control circuit 210D sets the gate current I_{LG_OFF} of the turn-off circuit 270D to a fourth current amount I₄. Then, in response to the assertion of the third output detection signal VOUTDET3, the gate current I_{LG_OFF} is set to a fifth current amount I₅ that is less than the fourth current amount I₄.

In response to the assertion of the low-side off signal LS_OFF, the control circuit 210D activates the high-side driver 220 and starts the turn-on operation of the high-side transistor MH.

Additionally, in response to the assertion of the low-side off signal LS_OFF, the control circuit 210D controls the turn-off circuit 270D to keep the gate-source voltage V_{LGS} of the low-side transistor ML at 0 V. For example, the turn-off circuit 270 may include an off-fixed switch connected between the gate and the source of the low-side transistor ML, and by turning on this off-fixed switch, the gate-source voltage V_{LGS} of the low-side transistor ML can be kept at 0 V.

By this control, EMI can be suppressed while reducing the power consumption of the low-side transistor ML.

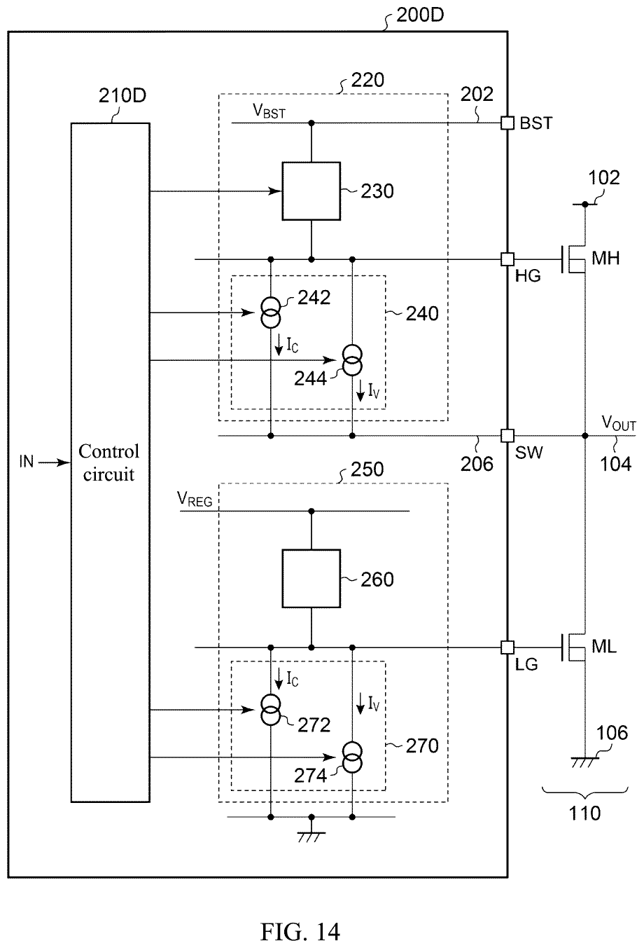

FIG. 14 is a circuit diagram of the gate driver circuit 200D according to Embodiment 2. The turn-off circuit 240 of the high-side driver 220 includes a third current source 242 and a fourth current source 244.

During the turn-off period t₀ to t₂ in FIG. 13, the third current source 242 sinks a constant amount of a third current I_{C} from the gate of the high-side transistor MH.

During the turn-off period t₀ to t₂, the fourth current source 244 sinks a fourth current I_{V} from the gate of the high-side transistor MH. A sum of the third current I_{C} and the fourth current I_{V} is the turn-off current I_{HG_OFF}. The fourth current source 244, similar to the second current source 234 in FIG. 5, includes transistors connected in parallel and individually controllable to be turned on and off. The transistors of the fourth current source 244 are N-channel MOSFETs.

The fourth current I_{V} is zero during the period t₀ to t₁ in FIG. 13 and can be non-zero during the period t₁ to t₂.

The turn-off circuit 270 of the low-side driver 250 is configured similarly to the turn-off circuit 240 of the high-side driver 220 and includes a third current source 272 and a fourth current source 274.

The third current source 272 sinks a constant amount of the third current I_{C} from the gate of the low-side transistor ML.

The fourth current source 274 sinks the fourth current I_{V} from the gate of the low-side transistor ML. The sum of the third current I_{C} and the fourth current I_{V} is the turn-off current I_{LG_OFF}. The fourth current source 274, similar to the fourth current source 274 in FIG. 5, includes transistors connected in parallel and individually controllable to be turned on and off. The transistors of the fourth current source 274 are N-channel MOSFETs.

With the gate driver circuit 200D in FIG. 14, the current becoming zero or glitches occurring at the timing of switching the current amount of the turn-off current can be prevented.

### Application

Next, applications of the switching circuit 100 are illustrated. The switching circuit 100 can be suitably used in motor driving circuits.

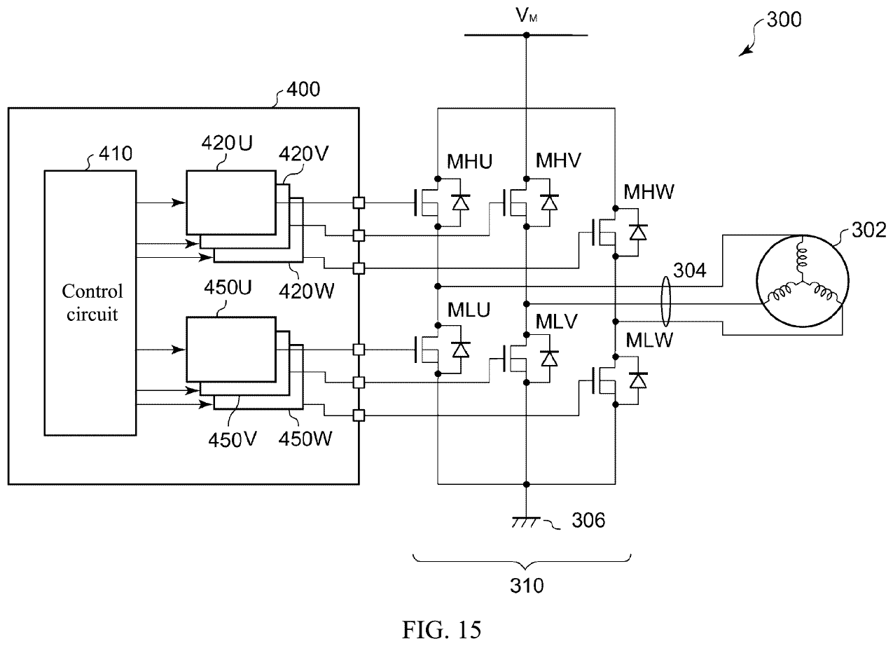

FIG. 15 is a circuit diagram of a motor driving device 300 according to an embodiment. The motor driving device 300 drives a three-phase motor 302, which is a load, and controls a rotational state.

The motor driving device 300 comprises a bridge circuit 310 and a gate driver circuit 400. The bridge circuit 310 is a three-phase inverter comprising U-phase, V-phase, and W-phase legs, and each phase leg comprises a high-side transistor MH and a low-side transistor ML.

The gate driver circuit 400 comprises a control circuit 410, high-side drivers 420U to 420W, and low-side drivers 450U to 450W. The control circuit 410 generates control signals that indicate states of six arms constituting the bridge circuit 310 based on a state of the three-phase motor 302, which is the load.

The high-side drivers 420U to 420W are configured based on an architecture of the aforementioned high-side driver 220. Additionally, the low-side drivers 450U to 450W are configured based on an architecture of the aforementioned low-side driver 250.

Although a three-phase motor is used as an example herein, a single-phase motor may also be used. In this case, the bridge circuit 310 would be an H-bridge circuit.

Next, applications of the motor driving device 300 are illustrated. The motor driving device 300 can be utilized to control a spindle motor of a hard disk, or to control a motor for driving lens of an imaging device. Alternatively, it can also be utilized for printer head driving motors or to drive paper feeding motors. Alternatively, the motor driving device 300 can be utilized to drive motors in electric vehicles, hybrid vehicles, etc.

The embodiments are examples, and it is understood by those skilled in the art that various modification examples are possible in combinations of each component and each processing step, and such modification examples are also within the scope of the present disclosure or the present invention. These modification examples are illustrated below.

### Modification Example 1

In an embodiment, the bridge circuit 110 is configured with discrete components, but this is not limitative, and the bridge circuit 110 may be integrated into the gate driver circuit 200.

### Modification Example 2

The power transistor may be configured as an IGBT (Insulated Gate Bipolar Transistor).

### Modification Example 3

The application of the switching circuit 100 is not limited to the motor driving device 300. For example, the switching circuit 100 can be suitably utilized in switching regulators (DC/DC converters), various power conversion devices (inverters and converters), inverters for lighting discharge lamps, digital audio amplifiers, etc. Therefore, the switching circuit 100 can be utilized in consumer devices including electronic equipment and home appliances, automobiles and in-vehicle components, industrial vehicles and industrial machinery.

The embodiments illustrated using specific terms are merely illustrative of principles and applications of the present invention, and many modification examples and changes in arrangement are permitted in the embodiments without departing from the spirit of the present invention as defined in the claims.

### Appendix

The following technologies are disclosed in this specification.

### (Item 1)

A gate driver circuit, driving an N-type power transistor, comprising:
a turn-on circuit sourcing a turn-on current to a gate of the power transistor during a turn-on period of the power transistor;
a turn-off circuit sinking a turn-off current from the gate of the power transistor during a turn-off period of the power transistor; and
a control circuit controlling the turn-on circuit and the turn-off circuit,
wherein the turn-on circuit includes:
a first current source sourcing a constant amount of a first current to the gate of the power transistor during the turn-on period; and
a second current source including a plurality of transistors connected in parallel and individually controllable to be turned on and off, wherein a combination of the plurality of transistors that are on changes over time during the turn-on period, and sourcing a second current, a current amount of which changes depending on the transistors that are on, to the gate of the power transistor,
wherein a sum of the first current and the second current is the turn-on current.

### (Item 2)

The gate driver circuit of Item 1, wherein the first current source includes:
a constant current source generating a reference current; and
a current mirror circuit copying the reference current and generating the first current.

### (Item 3)

The gate driver circuit of Item 1, wherein the first current source includes a plurality of transistors connected in parallel and individually controllable to be turned on and off, and a current amount of the first current depends on a combination of the plurality of transistors that are on.

### (Item 4)

The gate driver circuit of any of Items 1 to 3, wherein during a minimum current interval of a part of the turn-on period, the plurality of transistors of the second current source are all turned off and the second current is zero.

### (Item 5)

The gate driver circuit of Item 4, wherein during a first interval before the minimum current interval of the turn-on period, at least one of the plurality of transistors is turned on, and the second current source generates the second current, the current amount of which is non-zero.

### (Item 6)

The gate driver circuit of Item 5, wherein during a third interval after the minimum current interval of the turn-on period, at least one of the plurality of transistors is turned on, and the second current source generates the second current, the current amount of which is non-zero.

### (Item 7)

The gate driver circuit of Item 6, wherein the second current during the third interval is greater than the second current during the first interval.

### (Item 8)

The gate driver circuit of any of Items 1 to 7, wherein sizes of the plurality of transistors constituting the second current source are binary weighted.

### (Item 9)

The gate driver circuit of any of Items 1 to 8, wherein the turn-off circuit includes:
a third current source sinking a constant amount of a third current from the gate of the power transistor during the turn-off period; and
a fourth current source including a plurality of transistors connected in parallel and individually controllable to be turned on and off, wherein a combination of the plurality of transistors that are on changes over time during the turn-off period, and sinking a fourth current, a current amount of which changes depending on the transistors that are on, from the gate of the power transistor,
wherein a sum of the third current and the fourth current is the turn-off current.

### (Item 10)

A gate driver circuit, driving an N-type power transistor, comprising:
a turn-on circuit sourcing a turn-on current to a gate of the power transistor during a turn-on period of the power transistor;
a turn-off circuit sinking a turn-off current from the gate of the power transistor during a turn-off period of the power transistor; and
a control circuit controlling the turn-on circuit and the turn-off circuit,
wherein the turn-off circuit includes:
a third current source sinking a constant amount of a third current from the gate of the power transistor during the turn-off period; and
a fourth current source including a plurality of transistors connected in parallel and individually controllable to be turned on and off, wherein a combination of the plurality of transistors that are on changes over time during the turn-off period, and sinking a fourth current, a current amount of which changes depending on the transistors that are on, from the gate of the power transistor,
wherein a sum of the third current and the fourth current is the turn-off current.

### (Item 11)

The gate driver circuit of any of Items 1 to 10, being integrated on a single semiconductor substrate.

### (Item 12)

A motor driving device, comprising:
a bridge circuit including a high-side transistor and a low-side transistor;
a high-side driver being the gate driver circuit of any of Items 1 to 11 that drives the high-side transistor as the power transistor; and
a low-side driver being the gate driver circuit of any of Items 1 to 11 that drives the low-side transistor as the power transistor.

### (Item 13)

An electronic apparatus, comprising:
a motor; and
the motor driving device of Item 12 driving the motor.

1. A gate driver circuit, driving an N-type power transistor, comprising:
a turn-on circuit sourcing a turn-on current to a gate of the power transistor during a turn-on period of the power transistor;
a turn-off circuit sinking a turn-off current from the gate of the power transistor during a turn-off period of the power transistor; and
a control circuit controlling the turn-on circuit and the turn-off circuit,
wherein the turn-on circuit includes:
a first current source sourcing a constant amount of a first current to the gate of the power transistor during the turn-on period; and
a second current source including a plurality of transistors connected in parallel and individually controllable to be turned on and off, wherein a combination of the plurality of transistors that are on changes over time during the turn-on period, and sourcing a second current, a current amount of which changes depending on the transistors that are on, to the gate of the power transistor,
wherein a sum of the first current and the second current is the turn-on current.

2. The gate driver circuit of claim 1, wherein the first current source includes:
a constant current source generating a reference current; and
a current mirror circuit copying the reference current and generating the first current.

3. The gate driver circuit of claim 1, wherein the first current source includes a plurality of transistors connected in parallel and individually controllable to be turned on and off, and a current amount of the first current depends on a combination of the plurality of transistors that are on.

4. The gate driver circuit of claim 1, wherein during a minimum current interval of a part of the turn-on period, the plurality of transistors of the second current source are all turned off and the second current is zero.

5. The gate driver circuit of claim 4, wherein during a first interval before the minimum current interval of the turn-on period, at least one of the plurality of transistors is turned on, and the second current source generates the second current, the current amount of which is non-zero.

6. The gate driver circuit of claim 5, wherein during a third interval after the minimum current interval of the turn-on period, at least one of the plurality of transistors is turned on, and the second current source generates the second current, the current amount of which is non-zero.

7. The gate driver circuit of claim 6, wherein the second current during the third interval is greater than the second current during the first interval.

8. The gate driver circuit of claim 1, wherein sizes of the plurality of transistors constituting the second current source are binary weighted.

9. The gate driver circuit of claim 1, wherein the turn-off circuit includes:
a third current source sinking a constant amount of a third current from the gate of the power transistor during the turn-off period; and
a fourth current source including a plurality of transistors connected in parallel and individually controllable to be turned on and off, wherein a combination of the plurality of transistors that are on changes over time during the turn-off period, and sinking a fourth current, a current amount of which changes depending on the transistors that are on, from the gate of the power transistor,
wherein a sum of the third current and the fourth current is the turn-off current.

10. A gate driver circuit, driving an N-type power transistor, comprising:
a turn-on circuit sourcing a turn-on current to a gate of the power transistor during a turn-on period of the power transistor;
a turn-off circuit sinking a turn-off current from the gate of the power transistor during a turn-off period of the power transistor; and
a control circuit controlling the turn-on circuit and the turn-off circuit,
wherein the turn-off circuit includes:
a third current source sinking a constant amount of a third current from the gate of the power transistor during the turn-off period; and
a fourth current source including a plurality of transistors connected in parallel and individually controllable to be turned on and off, wherein a combination of the plurality of transistors that are on changes over time during the turn-off period, and sinking a fourth current, a current amount of which changes depending on the transistors that are on, from the gate of the power transistor,
wherein a sum of the third current and the fourth current is the turn-off current.

11. The gate driver circuit of claim 1, being integrated on a single semiconductor substrate.

12. A motor driving device, comprising:
a bridge circuit including a high-side transistor and a low-side transistor;
a high-side driver being the gate driver circuit of claim 1 that drives the high-side transistor as the power transistor; and
a low-side driver being the gate driver circuit that drives the low-side transistor as the power transistor.

13. An electronic apparatus, comprising:
a motor; and
the motor driving device of claim 12 driving the motor.
